(19) United States
(12) Patent Application Publication
(10) Pub. No.: US 2025/0355381 A1
(43) Pub. Date: Nov. 20, 2025

(54) EXPOSURE HEAD AND IMAGE-FORMING APPARATUS

(71) Applicant: CANON KABUSHIKI KAISHA, Tokyo (JP)

(72) Inventors: HAYATO KOYAMA, Chiba (JP); KOICHIRO NAKANISHI, Tokyo (JP); YASUTOMO FURUTA, Chiba (JP)

(21) Appl. No.: 19/282,304

(22) Filed: Jul. 28, 2025

Related U.S. Application Data
(63) Continuation of application No. 17/673,527, filed on Feb. 16, 2022.
Application No. 17/673,527 is a continuation of application No. PCT/JP2020/031198, filed on Aug. 19, 2020.

(30) Foreign Application Priority Data
Aug. 23, 2019 (JP) 2019-152978

(51) Int. Cl. G03G 15/04; B41J 2/45

(52) U.S. Cl. CPC G03G 15/04054; B41J 2/45

(57) ABSTRACT

An exposure head includes a plurality of light emitting element array chips. A first distance from a first side which is one of two long sides of each of the plurality of light emitting element array chips to one long side of a sealing area which is parallel to and proximate to the first side is shorter than a second distance from a second side which is another one of the two long sides to another long side of the sealing area which is parallel to and proximate to the second side, and a third distance from the first side to one long side of a light emitting area which is parallel to and proximate to the first side is shorter than a fourth distance from the second side to another long side of the light emitting area which is parallel to and proximate to the second side.

### CROSS-REFERENCE TO RELATED APPLICATIONS

This application is a Continuation of U.S. patent application Ser. No. 17/673,527 filed Feb. 16, 2022, which is a Continuation of International Patent Application No. PCT/JP2020/031198, filed Aug. 19, 2020, which claims the benefit of Japanese Patent Application No. 2019-152978, filed Aug. 23, 2019, each of which are hereby incorporated by reference herein in their entirety.

### BACKGROUND OF THE INVENTION

### Field of the Invention

The present invention relates to an exposure head and an image forming apparatus.

### Description of the Related Art

An electrophotographic image forming apparatus includes a photosensitive member to be driven to rotate, an exposure portion configured to expose the photosensitive member with light in order to form an electrostatic latent image, a developing portion configured to develop the electrostatic latent image formed on the photosensitive member through use of developer, and a transfer portion configured to transfer the image developed with the developer onto a sheet. In this case, as the exposure portion, a laser scanner, an exposure head, and the like are known. The laser scanner refers to an exposure device configured to deflect light emitted from a light source by a deflecting member so that the light emitted from the light source is scanned onto the surface of the photosensitive member. Meanwhile, the exposure head refers to an exposure device which does not include the deflecting member, and in which a plurality of light sources are arranged side by side in a direction orthogonal to a direction in which the surface of the photosensitive member is moved. The exposure head includes a lens array configured to image light emitted from a plurality of light emitting elements onto the photosensitive member.

In the exposure head described in Japanese Patent Application Laid-Open No. 2015-162428, in order to suppress deterioration of a plurality of organic ELs (electro-luminescences) serving as light sources due to moisture and oxygen, the organic ELs are sealed by bonding an organic EL circuit board and a driver IC board to each other by metal joining. Further, in the exposure head described in Japanese Patent Application Laid-Open No. 2015-162428, a plurality of organic EL circuit boards are arranged in a staggered manner. The reason for this arrangement is because, as compared to an exposure head including one long organic EL circuit board, the manufacturing cost can be reduced.

In an exposure head in which light emitting element array chips each formed of a plurality of light emitting elements are arranged in a staggered manner on a circuit board, from the viewpoint of light utilization efficiency, it is preferred that a distance between a light emitting area of each light emitting element array chip and a center of the lens array be reduced. However, a sealing material for sealing the light emitting area is required in order to suppress entry of moisture and oxygen from an end portion of the light emitting element array chip, and hence the distance between the light emitting area and the center of the lens array is increased, which results in a problem in that the light utilization efficiency is reduced.

In view of the above, the present invention has an object to suppress reduction of light utilization efficiency of an exposure head.

### SUMMARY OF THE INVENTION

In order to solve the above-mentioned problem, according to an embodiment of the present invention, there is provided an exposure head comprising: a plurality of light emitting element array chips; a light emitting area which is provided in each of the plurality of light emitting element array chips, and includes a plurality of light emitting portions; a sealing material for covering a light emitting face of the light emitting area and a side face of the light emitting area; and a lens array configured to condense light emitted from the light emitting area, wherein, as viewed from the light emitting face side, a sealing area applied with the sealing material includes the light emitting area, wherein each of the plurality of light emitting element array chips has a rectangular shape, wherein a first distance from a first side which is one of two long sides of each of the plurality of light emitting element array chips to one long side of the sealing area which is parallel to and proximate to the first side is shorter than a second distance from a second side which is another one of the two long sides of each of the plurality of light emitting element array chips to another long side of the sealing area which is parallel to and proximate to the second side, and wherein a third distance from the first side to one long side of the light emitting area which is parallel to and proximate to the first side is shorter than a fourth distance from the second side to another long side of the light emitting area which is parallel to and proximate to the second side.

Further features of the present invention will become apparent from the following description of exemplary embodiments with reference to the attached drawings.

### BRIEF DESCRIPTION OF THE DRAWINGS

FIG. 1 is a sectional view of an image forming apparatus.

FIG. 2A is a view for illustrating arrangement of an exposure head with respect to a photosensitive drum.

FIG. 2B is a view for illustrating a light flux emitted from a light emitting element group to be condensed onto the photosensitive drum by a rod lens array.

FIG. 3A is a view for illustrating a light emitting element non-mounting surface of a printed circuit board.

FIG. 3B is a view for illustrating a light emitting element mounting surface of the printed circuit board.

FIG. 3C is a view for illustrating a boundary portion between light emitting element array chips.

FIG. 4A is a plan view of a light emitting element array chip.

FIG. 4B is a view for illustrating the boundary portion between the light emitting element array chips.

FIG. 5 is a partially enlarged sectional view of the light emitting element array chip taken along the line V-V of FIG. 4A.

FIG. 6A is a view for illustrating a light emitting area in which a plurality of light emitting portions are arranged in a row.

FIG. 6B is a sectional view of a light emitting array.

FIG. 7 is a block diagram of an image controller portion and the printed circuit board.

FIG. 8 is a block diagram of a circuit portion included in the light emitting element array chip.

FIG. 9 is a block diagram of an analog portion.

FIG. 10 is a diagram for illustrating a drive circuit of a drive portion.

### DESCRIPTION OF THE EMBODIMENTS

### Image Forming Apparatus

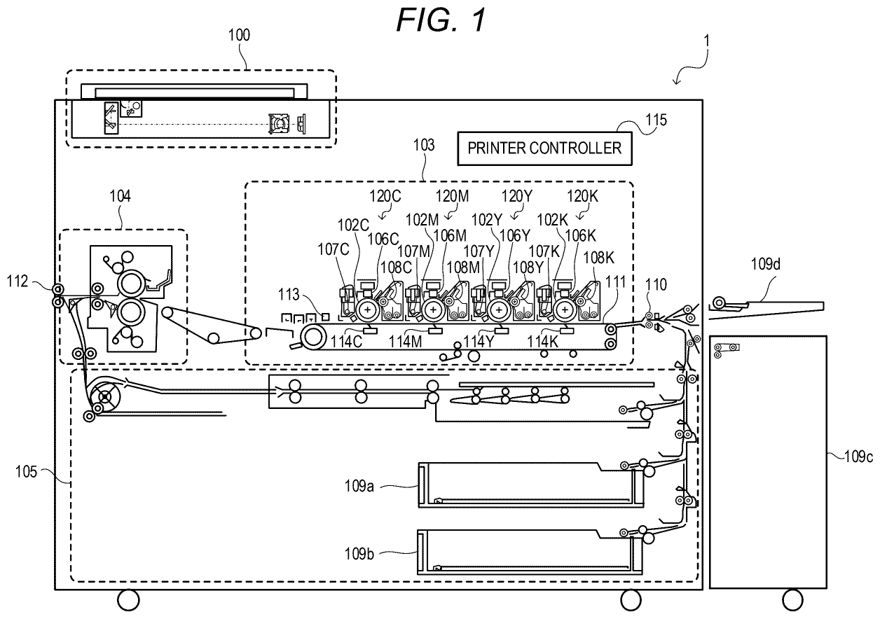

With reference to FIG. 1, an electrophotographic image forming apparatus 1 according to an embodiment is described. FIG. 1 is a sectional view of the image forming apparatus 1. The image forming apparatus 1 is a multifunction printer (MFP). The image forming apparatus 1 includes a scanner portion 100, an image forming portion 103, a fixing portion 104, a feeding/conveying portion 105, and a printer controller 115. The printer controller 115 controls the scanner portion 100, the image forming portion 103, the fixing portion 104, and the feeding/conveying portion 105. The scanner portion 100 illuminates an original placed on an original table, and optically reads reflected light reflected from the original. The scanner portion 100 converts the read reflected light into an electrical signal to generate image data. The image forming portion 103 includes four image forming units 120C, 120M, 120Y, and 120K for performing a series of electrophotographic processes (charging, exposure, development, and transfer). The four image forming units 120C, 120M, 120Y, and 120K are arranged side by side in order of cyan (C), magenta (M), yellow (Y), and black (K) to form a full-color image. In the four image forming units 120C, 120M, 120Y, and 120K, after a predetermined time period has elapsed from the start of the image formation by the cyan image forming unit 120C, image forming operations of magenta, yellow, and black are sequentially performed. The suffixes “C”, “M”, “Y”, and “K” of the reference symbols represent cyan, magenta, yellow, and black, respectively. In the following description, the suffixes “C”, “M”, “Y”, and “K” of the reference symbols are sometimes omitted unless particularly required.

The image forming portion 103 causes photosensitive drums 102C, 102M, 102Y, and 102K to rotate. Chargers 107C, 107M, 107Y, and 107K uniformly charge the surfaces of the photosensitive drums 102C, 102M, 102Y, and 102K, respectively. Exposure heads 106C, 106M, 106Y, and 106K emit light in accordance with the image data to form electrostatic latent images on the surfaces of the photosensitive drums 102C, 102M, 102Y, and 102K, respectively. Developing devices 108C, 108M, 108Y, and 108K develop the electrostatic latent images formed on the surfaces of the photosensitive drums 102C, 102M, 102Y, and 102K with toners of respective colors to obtain toner images of cyan, magenta, yellow, and black, respectively.

The image forming apparatus 1 includes internal feeding units 109a and 109b, an external feeding unit 109c, and a manual feeding unit 109d. The feeding/conveying portion 105 feeds a sheet serving as a recording medium to which an image is to be formed, from a feeding unit designated in advance among the internal feeding units 109a and 109b, the external feeding unit 109c, and the manual feeding unit 109d. The fed sheet is conveyed to registration rollers 110. The registration rollers 110 convey the sheet onto a transfer belt 111 so that the toner images formed in the image forming portion 103 are transferred onto the sheet.

The toner images of cyan, magenta, yellow, and black formed on the surfaces of the photosensitive drums 102C, 102M, 102Y, and 102K are sequentially transferred and superimposed onto the sheet conveyed on the transfer belt 111 by transfer devices 114C, 114M, 114Y, and 114K, respectively. The sheet having the toner images transferred thereon is conveyed to the fixing portion (fixing device) 104. The fixing portion 104 includes a heating roller and a pressure roller. The heating roller incorporates a halogen heater as a heat source. The pressure roller is brought into pressure-contact with the heating roller. The fixing portion 104 melts the toner images formed on the sheet by heat and pressure to fix the toner images to the sheet. In this manner, a full-color image is formed on the sheet. The sheet having the image formed thereon is delivered to the outside of the image forming apparatus 1 by delivery rollers 112.

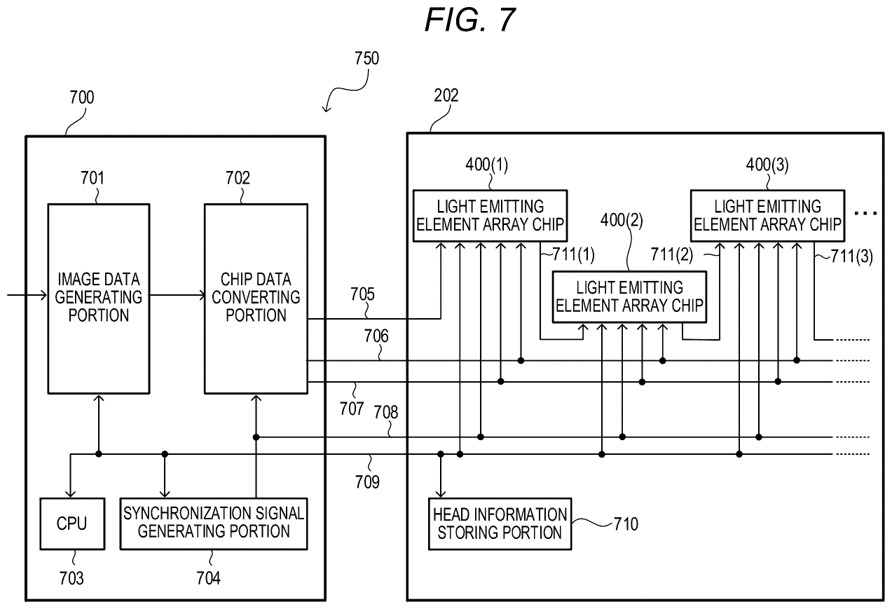

An optical sensor 113 is arranged to be opposed to the transfer belt 111. The optical sensor 113 detects a position of a toner image of a test chart transferred onto the transfer belt 111. A color misregistration amount of the toner image of each color is calculated based on a detection result obtained by the optical sensor 113. The color misregistration amount is input to an image controller portion 700 (FIG. 7). The image controller portion 700 corrects an image position of each color based on the color misregistration amount. With the color misregistration correction control performed by the image controller portion 700, a full-color toner image without color misregistration is transferred onto the sheet.

The printer controller 115 communicates to/from an MFP controller (not shown) for controlling the entire image forming apparatus 1. The printer controller 115 reads an image of the original in accordance with an instruction from the MFP controller (not shown), and gives an instruction to each portion so that the entire apparatus can smoothly operate with harmony while managing states of forming and fixing of the toner images and feeding/conveying of the sheet.

### Exposure Head

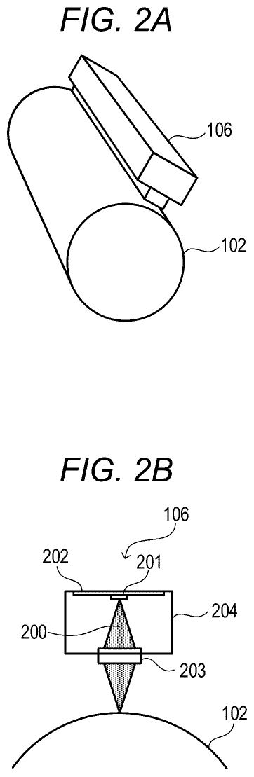

Next, with reference to FIG. 2A and FIG. 2B, the exposure head 106 configured to expose the photosensitive drum 102 with light is described. FIG. 2A and FIG. 2B are views for illustrating the arrangement of the photosensitive drum 102 and the exposure head 106. FIG. 2A is a view for illustrating the arrangement of the exposure head 106 with respect to the photosensitive drum 102. FIG. 2B is a view for illustrating a light flux 200 emitted from a light emitting element group 201 to be condensed onto the photosensitive drum 102 by a rod lens array 203. The exposure head 106 and the photosensitive drum 102 are mounted to the image forming apparatus 1 by a mounting member (not shown). The exposure head 106 includes the light emitting element group 201, a printed circuit board 202 having the light emitting element group 201 mounted thereon, the rod lens array 203, and a housing 204 to which the rod lens array 203 and the printed circuit board 202 are mounted. At the factory, work of assembling and adjusting the exposure head 106 alone is performed. In the assembling and adjusting work, there are performed light amount adjustment and focus adjustment for adjusting a spot formed at a light condensing position to a predetermined size. In this case, the rod lens array 203 is arranged so that a distance between the photosensitive drum 102 and the rod lens array 203 and a distance between the rod lens array 203 and the light emitting element group 201 are predetermined distances. In this manner, the light flux 200 emitted from the light emitting element group 201 is imaged onto the photosensitive drum 102 by the rod lens array 203. In the focus adjustment, the position to mount the rod lens array 203 is adjusted so that the distance between the rod lens array 203 and the light emitting element group 201 takes a predetermined value. Further, in the light amount adjustment, light emitting elements of the light emitting element group 201 are individually caused to sequentially emit light, and a drive current of each light emitting element is adjusted so that the light amount of light condensed by the rod lens array 203 takes a predetermined value.

### Printed Circuit Board

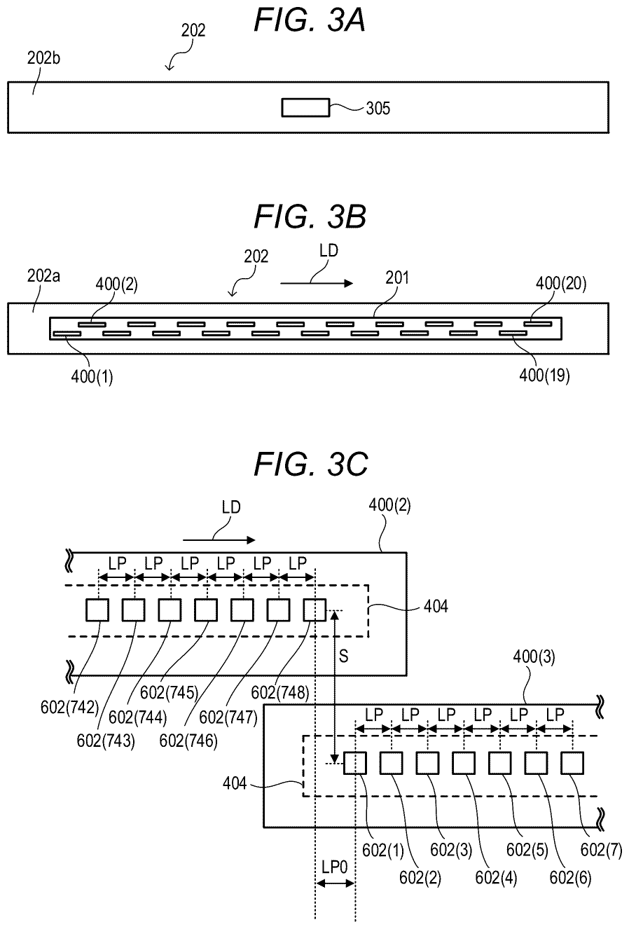

Next, with reference to FIG. 3A, FIG. 3B, and FIG. 3C, the printed circuit board 202 having the light emitting element group 201 mounted thereon is described. FIG. 3A, FIG. 3B, and FIG. 3C are views for illustrating the printed circuit board 202. The printed circuit board 202 has a surface 202a on which the light emitting element group 201 is mounted (hereinafter referred to as “light emitting element mounting surface”), and a surface 202b opposite to the light emitting element mounting surface 202a (hereinafter referred to as “light emitting element non-mounting surface”). FIG. 3A is a view for illustrating the light emitting element non-mounting surface 202b of the printed circuit board 202. A connector 305 is arranged on the light emitting element non-mounting surface 202b. The connector 305 is connected to a control signal cable from the image controller portion 700 (FIG. 7) and a power cable from a power supply (not shown). The control signal cable includes a chip select signal line 705, a clock signal line 706, an image data signal line 707, a line synchronization signal line 708, and a communication signal line 709, which are to be described later with reference to FIG. 7. FIG. 3B is a view for illustrating the light emitting element mounting surface 202a of the printed circuit board 202. The light emitting element group 201 is formed of 20 light emitting element array chips 400(1), 400(2), . . . , 400(19), and 400(20) arranged alternately, that is, in a staggered manner. The light emitting element array chips 400(1) to 400(20) receive, as an input, a control signal from the image controller portion 700 via the connector 305, and are supplied with power from the power supply (not shown) to be driven. The light emitting element array chip 400 has a rectangular shape.

FIG. 3C is a view for illustrating a boundary portion between the light emitting element array chip 400(2) and the light emitting element array chip 400(3). In a light emitting area 404 of each of the light emitting element array chips 400(1) to 400(20), a plurality of light emitting portions 602 are formed at predetermined pitches LP in a longitudinal direction LD of the exposure head 106. The longitudinal direction LD is a direction orthogonal to a direction in which the surface of the photosensitive drum 102 is moved. In the embodiment, one light emitting element array chip 400 includes 748 light emitting portions 602 as light emitting points. The light emitting portion 602 may be a surface emitting element such as a surface emitting laser or a surface emission-type diode. The light emitting portion 602 may be a bottom emission-type organic EL (electro-luminescence) or LED (light emission diode), or a top emission-type organic EL or LED. In the embodiment, the predetermined pitch LP of the light emitting portions 602 adjacent to each other in the longitudinal direction LD is a pitch (about 21.16 μm) at a resolution of 1,200 dpi. An end-to-end distance of the 748 light emitting portions 602 in the light emitting area 404 of the light emitting element array chip 400 is about 15.8 mm. The light emitting element group 201 includes 20 light emitting element array chips 400, and thus includes 14,960 light emitting portions 602. Thus, an image having a width of about 316 mm can be formed. The light emitting element array chips 400(1) to 400(20) are arranged in two rows in a staggered manner. The light emitting element array chips 400(1) to 400(20) are arranged along the longitudinal direction LD of the exposure head 106. For example, the light emitting element array chip 400(1) and the light emitting element array chip 400(3) are arranged to be shifted from the light emitting element array chip 400(2) and the light emitting element array chip 400(4) in the direction in which the surface of the photosensitive drum 102Y is moved. Further, the light emitting element array chips 400(1) to 400(20) have a plurality of areas overlapping in the longitudinal direction LD of the exposure head 106.

As illustrated in FIG. 3C, even at the boundary portion between the light emitting element array chips 400(between the chips), a pitch LP0 between the light emitting portions 602(748) and 602(1) in the longitudinal direction LD is a pitch (about 21.16 μm) at the resolution of 1,200 dpi (LP0=LP). Further, the light emitting element array chips 400 are arranged so that, in a direction perpendicular to the longitudinal direction LD, an interval S between the light emitting portions 602 of the light emitting element array chips 400 in the two rows is about 105 μm (interval corresponding to five pixels at 1,200 dpi).

### Light Emitting Element Array Chip

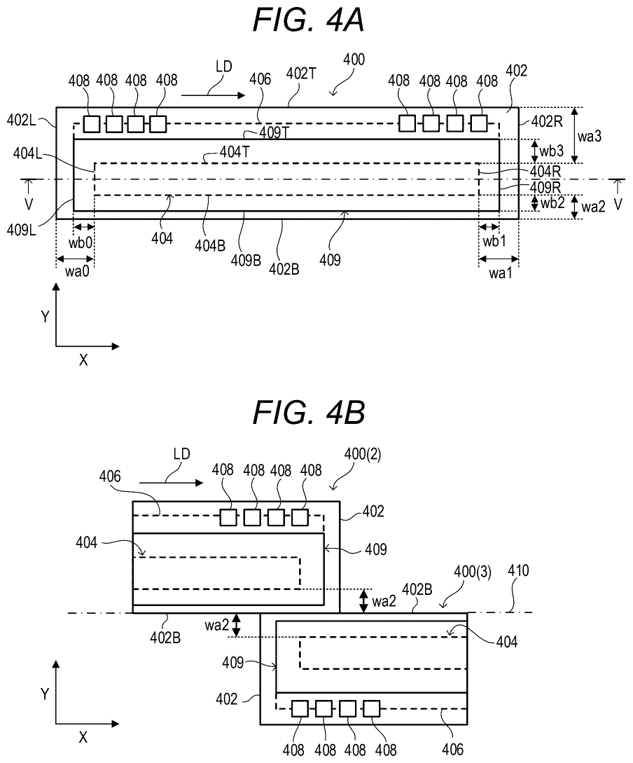

Next, with reference to FIG. 4A and FIG. 4B, the light emitting element array chip 400 is described. FIG. 4A and FIG. 4B are views for illustrating the light emitting element array chip 400. In FIG. 4A and FIG. 4B, an X direction indicates the longitudinal direction LD of the exposure head 106, and a Y direction indicates a rotation direction of the photosensitive drum 102. FIG. 4A is a plan view of the light emitting element array chip 400. The light emitting element array chip 400 includes a light emitting circuit board 402, the light emitting area 404, a plurality of wire bonding pads (WB pads) 408, and a sealing area 409. The light emitting area 404 includes the plurality of light emitting portions 602 arrayed on the light emitting circuit board 402. The plurality of wire bonding pads (WB pads) 408 are formed on the light emitting circuit board 402. The wire bonding pads 408 are electrically connected to the printed circuit board 202 by metal lines. The light emitting circuit board 402 incorporates a circuit portion 406 serving as a control circuit for controlling the drive of the light emitting area 404. As the circuit portion 406, an analog drive circuit, a digital control circuit, or a circuit including both of those circuits can be used. The supply of power to the circuit portion 406 and the input/output of a signal to/from the outside of the light emitting element array chip 400 are performed through the wire bonding pads 408.

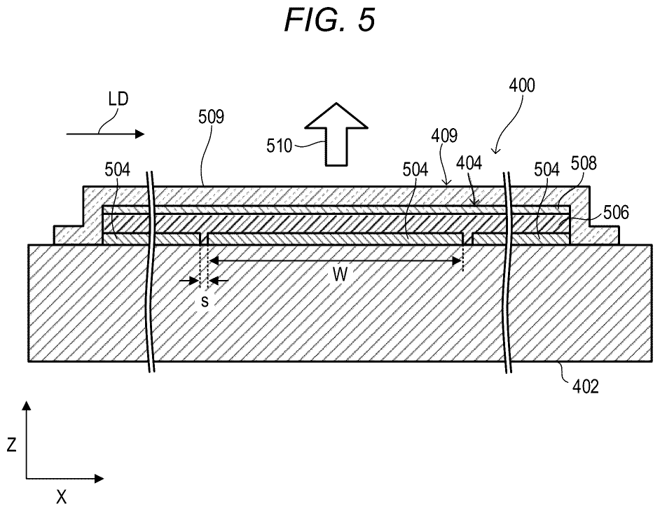

The sealing area 409 is an area including the light emitting area 404 and its surrounding. In the sealing area 409, a sealing layer 509 (FIG. 5) made of a sealing material covers a light emitting face of the light emitting area 404 and a side face of the light emitting area 404, and an upper face of the light emitting circuit board 402 around the light emitting area 404 (face on the light emitting face side from which light is emitted). As viewed from the light emitting face side, the sealing area 409 applied with the sealing material includes the light emitting area 404. The sealing layer 509 is to be described later. As illustrated in FIG. 4A, a distance from a left side 404L of the light emitting area 404 to a left side 409L of the sealing area 409 is represented by wb0, and a distance from the left side 404L of the light emitting area 404 to a left side 402L of the light emitting circuit board 402 is represented by wa0. A distance from a right side 404R of the light emitting area 404 to a right side 409R of the sealing area 409 is represented by wb1, and a distance from the right side 404R of the light emitting area 404 to a right side 402R of the light emitting circuit board 402 is represented by wa1. A distance from a lower side 404B of the light emitting area 404 to a lower side 409B of the sealing area 409 is represented by wb2, and a distance from the lower side 404B of the light emitting area 404 to a lower side 402B of the light emitting circuit board 402 is represented by wa2. A distance from an upper side 404T of the light emitting area 404 to an upper side 409T of the sealing area 409 is represented by wb3, and a distance from the upper side 404T of the light emitting area 404 to an upper side 402T of the light emitting circuit board 402 is represented by wa3.

A distance from the lower side (first side) 402B which is one of two long sides of the light emitting element array chip 400 to the lower side (one long side) 409B of the sealing area 409 which is parallel to and proximate to the lower side 402B is represented by a first distance (wa2-wb2). A distance from the upper side (second side) 402T which is another one of the two long sides of the light emitting element array chip 400 to the upper side (another long side) 409T of the sealing area 409 which is parallel to and proximate to the upper side 402T is represented by a second distance (wa3-wb3). It is preferred that the first distance (wa2-wb2) be shorter than the second distance (wa3-wb3). The distance wa2 from the lower side (first side) 402B of the light emitting element array chip 400 to the lower side (one long side) 404B of the light emitting area 404 which is parallel to and proximate to the lower side 402B is represented by a third distance wa2. The distance wa3 from the upper side (second side) 402T of the light emitting element array chip 400 to the upper side (another long side) 404T of the light emitting area 404 which is parallel to and proximate to the upper side 402T is represented by a fourth distance wa3. It is preferred that the third distance wa2 be shorter than the fourth distance wa3.

A distance from the left side (third side) 402L which is one of two short sides of the light emitting element array chip 400 to the left side (one short side) 409L of the sealing area 409 which is parallel to and proximate to the left side 402L is represented by a fifth distance (wa0-wb0). A distance from the right side (fourth side) 402R which is another one of the two short sides of the light emitting element array chip 400 to the right side (another short side) 409R of the sealing area 409 which is parallel to and proximate to the right side 402R is represented by a sixth distance (wa1-wb1). It is preferred that the first distance (wa2-wb2) be shorter than the fifth distance (wa0-wb0) and the sixth distance (wa1-wb1).

The distance wa0 from the left side (third side) 402L which is one of the two short sides of the light emitting element array chip 400 to the left side (one short side) 404L of the light emitting area 404 which is parallel to and proximate to the left side 402L is represented by a seventh distance wa0. The distance wa1 from the right side (fourth side) 402R which is another one of the two short sides of the light emitting element array chip 400 to the right side (another short side) 404R of the light emitting area 404 which is parallel to and proximate to the right side 402R is represented by an eighth distance wa1. It is preferred that the third distance wa2 be shorter than the seventh distance wa1 and the eighth distance wa1.

In the embodiment, the position of the light emitting area 404 with respect to the light emitting circuit board 402 is determined so that, among the distances wa0, wa1, wa2, and wa3, the distance wa2 is the minimum. Further, the sealing area 409 is formed so that, among the distances wb0, wb1, wb2, and wb3, the distance wb2 is the minimum. The distance wb2 has a length sufficient for sealing the light emitting area 404. When the distance wb2 is set to be the minimum as described above, the distance wa2 between one side along the longitudinal direction LD (in FIG. 4A, the lower side 402B) and the lower side 404B of the light emitting area 404 can be minimized.

With reference to FIG. 4B, the boundary portion (joint part) of adjacent light emitting element array chips 400 is described. In the embodiment, the plurality of light emitting element array chips 400 are arranged in a staggered manner along one straight line 410 extending in the longitudinal direction LD so that sides each having the minimum distance from the light emitting area 404 are opposed to each other. It is preferred that the straight line 410 be a center line of the exposure head 106, but the straight line 410 is not always required to be the center line. FIG. 4B is a view for illustrating, as an example, the boundary portion between the light emitting element array chip 400(2) and the light emitting element array chip 400(3). The lower side 402B of the light emitting circuit board 402 of the light emitting element array chip 400(2) and the lower side 402B of the light emitting circuit board 402 of the light emitting element array chip 400(3) are arranged on the straight line 410 to be opposed to each other. As described above, the plurality of light emitting element array chips 400 are arranged in a staggered manner along the straight line 410 so that the lower sides (first sides) 402B of the adjacent light emitting element array chips 400 are partially opposed to each other. A distance between the light emitting areas 404 of the adjacent light emitting element array chips 400 in the Y direction is two times the distance wa2. The distance between each light emitting area 404 and the straight line 410 is minimized. When the rod lens array 203 is arranged on the straight line 410, the distance between the rod lens array 203 and the light emitting area 404 is also minimized. In this manner, the reduction of the light utilization efficiency can be suppressed to the minimum.

### Light Emitting Area

Next, with reference to FIG. 5, the light emitting area 404 is described. FIG. 5 is a partially enlarged sectional view of the light emitting element array chip 400 taken along the line V-V of FIG. 4A. A Z direction of FIG. 5 is a direction which is perpendicular to the X direction and the Y direction and in which emission light 510 is emitted from the light emitting area 404. The light emitting area 404 includes a plurality of lower electrodes 504, a light emitting layer 506, and an upper electrode 508. In the sealing area 409, the sealing layer 509 for sealing the light emitting area 404 is formed. The plurality of lower electrodes 504 are formed on the light emitting circuit board 402. The light emitting layer 506 is formed on the plurality of lower electrodes 504 formed on the light emitting circuit board 402. The upper electrode 508 is formed on the light emitting layer 506. The sealing layer 509 is formed above the light emitting layer 506.

The lower electrode 504 is an independent electrode. The upper electrode 508 is a common electrode. As illustrated in FIG. 5, the lower electrode 504 has a width W in the X direction parallel to the longitudinal direction LD. In the light emitting area 404, a plurality of (in the embodiment, 748) lower electrodes 504 are formed at intervals “s” in the X direction. The light emitting layer 506 is formed between the upper electrode 508 and the lower electrodes 504. The light emitting layer 506 may be successively formed, or may be formed to be divided into a size substantially equivalent to that of the lower electrode 504. The light emitting layer 506 is energized via the upper electrode 508 and the lower electrode 504 selected from the plurality of lower electrodes 504, and thus a part of the light emitting layer 506 corresponding to the selected lower electrode 504 emits light so that the emission light 510 is emitted through the upper electrode 508. The lower electrode 504 is made of silver (Ag) having a reflectance higher than a light emission wavelength of the light emitting layer 506. However, the lower electrode 504 may be made of aluminum (Al), an alloy thereof, or other metals.

The upper electrode 508 is made of a material which is transparent with respect to the light emission wavelength of the light emitting layer 506, and hence the upper electrode 508 transmits the emission light 510 emitted from the light emitting layer 506. In the embodiment, the upper electrode 508 is made of indium tin oxide (ITO). The light emitting layer 506 is formed of, for example, an organic EL film. However, the light emitting layer 506 may be formed of an inorganic EL film instead of the organic EL film. The sealing layer 509 is formed to cover the upper face and the side face of the upper electrode 508, the side face of the light emitting layer 506, the side faces of the lower electrodes 504, and the upper face of the light emitting circuit board 402 around the light emitting area 404. The sealing layer 509 does not pass oxygen and moisture therethrough, and a sealing material which is transparent with respect to the light emission wavelength of the light emitting layer 506 is used therefor.

### Array of Light Emitting Elements

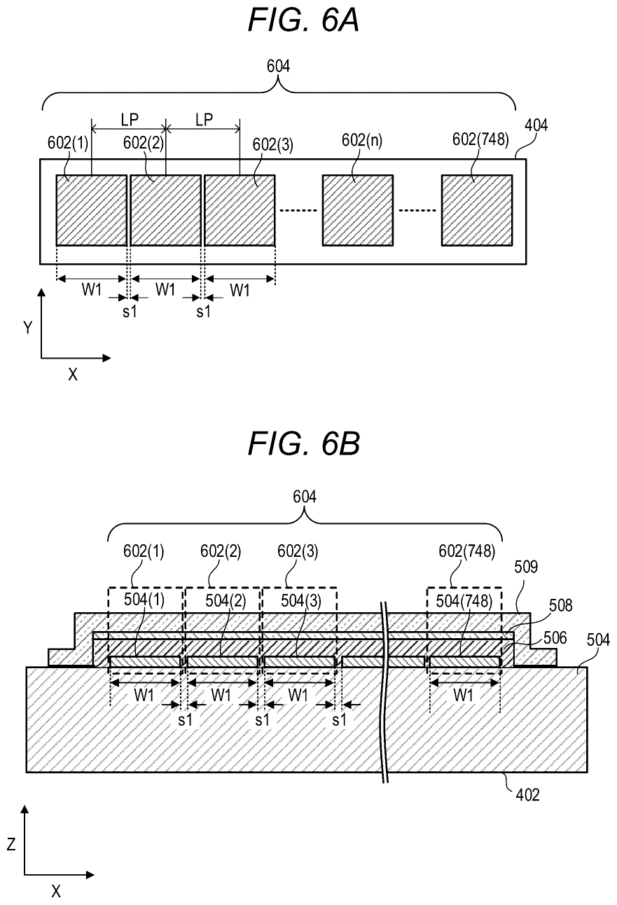

Now, with reference to FIG. 6A and FIG. 6B, the light emitting portions 602 on the light emitting area 404 are described. FIG. 6A and FIG. 6B are views of the light emitting portions 602. FIG. 6A is a view for illustrating the light emitting area 404 in which the plurality of light emitting portions 602 are arranged in a row. The plurality of light emitting portions 602(1), 602(2), 602(3), . . . , and 602(n) are arranged at predetermined pitches LP in the X direction to form a light emitting array 604. For example, when the resolution is 1,200 dpi, the predetermined pitch is 21.16 μm. The light emitting portion 602 has a width W1 in the X direction. Adjacent light emitting portions 602 have an interval sl in the X direction. When the light emitting layer 506 is sufficiently thin, the dimensions of the light emitting portion 602 are substantially the same as the dimensions of the lower electrode 504. In the embodiment, the width W1 of the light emitting portion 602 may be regarded as the width W of the lower electrode 504 illustrated in FIG. 5. The interval s1 of the adjacent light emitting portions 602 may be regarded as the interval “s” of the adjacent lower electrodes 504 illustrated in FIG. 5. In the embodiment, the width W1 of the light emitting portion 602 is 20.9 μm. The interval s1 of the adjacent light emitting portions 602 is 0.26 μm.

FIG. 6B is a sectional view of the light emitting array 604. As illustrated in FIG. 6B, each of the plurality of (in the embodiment, 748) lower electrodes 504 has the width W1 in the X direction. The plurality of lower electrodes 504 are arranged at intervals s1 in the X direction to form the light emitting array 604. Each of the light emitting portions 602 is formed of the lower electrode 504, a part of the upper electrode 508 opposed to the lower electrode 504, and a part of the light emitting layer 506 between the lower electrode 504 and the part of the upper electrode 508. In FIG. 6B, the light emitting portion 602 is indicated by a part surrounded by the dotted line.

### Controller

Next, with reference to FIG. 7, a controller 750 is described. The controller 750 includes the image controller portion 700 and the printed circuit board 202. FIG. 7 is a block diagram of the image controller portion 700 and the printed circuit board 202. In this case, for the sake of simplifying the description, single-color processing performed by the controller 750 is described, but the controller 750 can perform similar processing in parallel simultaneously for four colors. The image controller portion 700 includes an image data generating portion 701, a chip data converting portion 702, a CPU (central processing unit) 703, and a synchronization signal generating portion 704. The printed circuit board 202 includes the light emitting element array chips 400(1), 400(2), 400(3), . . . , and 400(20) and a head information storing portion 710.

### Image Controller Portion

The image controller portion 700 transmits, to the printed circuit board 202, a control signal for controlling the printed circuit board 202. The control signal includes a chip select signal representing an effective range of the image data, a clock signal, image data, a signal representing a section for each line of the image data (hereinafter referred to as “line synchronization signal”), and a communication signal for communication to/from the CPU 703. The chip select signal, the clock signal, and the image data are transmitted from the chip data converting portion 702 of the image controller portion 700 to the light emitting element array chip 400 via the chip select signal line 705, the clock signal line 706, and the image data signal line 707, respectively. The line synchronization signal is transmitted from the synchronization signal generating portion 704 of the image controller portion 700 to the light emitting element array chip 400 via the line synchronization signal line 708. The communication signal is transmitted from the CPU 703 to the light emitting element array chip 400 and the head information storing portion 710 via the communication signal line 709.

The image controller portion 700 performs processing for the image data and processing for the print timing. The image data generating portion 701 performs dithering at a resolution given as an instruction by the CPU 703 with respect to the image data (image signal) received from the scanner portion 100 or an external apparatus, and generates image data for print output. In the embodiment, the dithering is performed at the resolution of 1,200 dpi.

The synchronization signal generating portion 704 generates the line synchronization signal. The CPU 703 gives, to the synchronization signal generating portion 704, an instruction of a time interval of a signal cycle assuming, as one line cycle, a cycle in which the surface of the photosensitive drum 102 is moved by a pixel size of 1,200 dpi (about 21.16 μm) in the rotation direction (Y direction) at a predetermined rotation speed. For example, when printing is performed at a speed of 200 mm/s in a sheet conveyance direction (Y direction), the CPU 703 gives, to the synchronization signal generating portion 704, an instruction of the time interval assuming one line cycle as 105.8 μs (numbers at and below two decimal places are omitted). The CPU 703 uses a set value (fixed value) of the print speed set in speed control means (not shown) for controlling a speed of the photosensitive drum 102 to calculate the speed in the sheet conveyance direction.

The chip data converting portion 702 divides, for each light emitting element array chip 400, the image data corresponding to one line in synchronization with the line synchronization signal generated by the synchronization signal generating portion 704. The chip data converting portion 702 transmits the divided image data pieces to the printed circuit board 202 together with the clock signal and the chip select signal.

### Printed Circuit Board

Next, the configuration of the printed circuit board 202 is described. The head information storing portion 710 is a storage device for storing head information on, for example, the light emitting amount of each light emitting element array chip 400 and mounting position information. The head information storing portion 710 is connected to the CPU 703 via the communication signal line 709. The clock signal line 706, the image data signal line 707, the line synchronization signal line 708, and the communication signal line 709 are connected to all of the light emitting element array chips 400. The chip select signal line 705 is connected to an input of the light emitting element array chip 400(1). An output of the light emitting element array chip 400(1) is connected to an input of the light emitting element array chip 400(2) via a chip select signal line 711(1). An output of the light emitting element array chip 400(2) is connected to an input of the light emitting element array chip 400(3) via a chip select signal line 711(2). In a similar manner, a chip select signal line is cascade connected to each of the light emitting element array chips 400. Each of the light emitting element array chips 400 applies a current between the upper electrode 508 and the lower electrode 504 based on a set value set depending on the input chip select signal, clock signal, line synchronization signal, image data, and communication signal. In this manner, the light emitting layer 506 (light emitting portion 602) between the upper electrode 508 and the lower electrode 504 emits light. Further, each of the light emitting element array chips 400 generates a chip select signal for the next light emitting element array chip 400.

### Circuit Portion Included in Light Emitting Element Array Chip

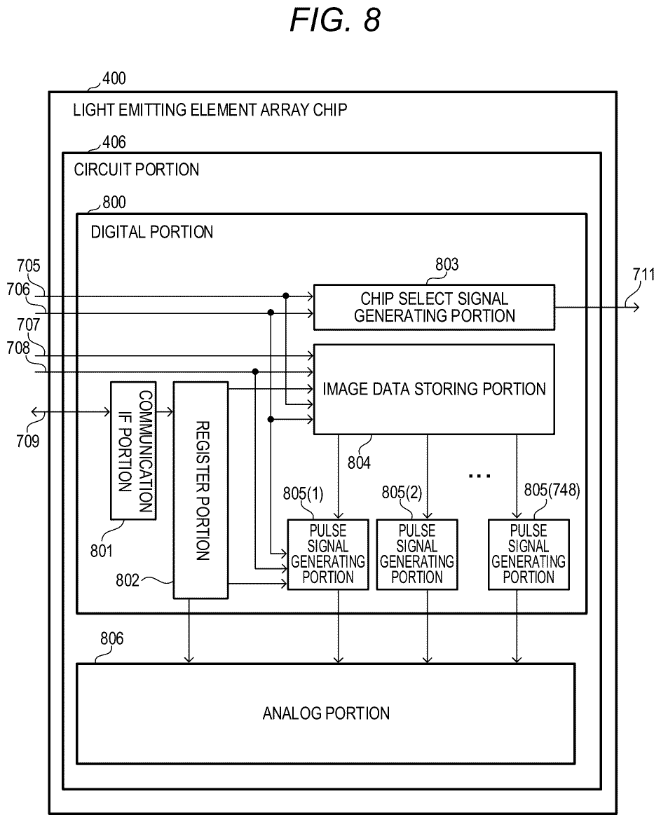

FIG. 8 is a block diagram of a circuit portion 406 included in the light emitting element array chip 400. The circuit portion 406 included in the light emitting element array chip 400 is formed of a digital portion 800 and an analog portion 806. To the digital portion 800, the clock signal, the communication signal, the chip select signal, the image data, and the line synchronization signal are input via the clock signal line 706, the communication signal line 709, the chip select signal line 705, the image data signal line 707, and the line synchronization signal line 708, respectively. The digital portion 800 has a function of generating a pulse signal for causing the light emitting portion 602 to emit light in synchronization with the clock signal, based on a set value set in advance by the communication signal, the chip select signal, the image data, and the line synchronization signal. The digital portion 800 transmits the pulse signal to the analog portion 806. Further, the digital portion 800 has a function of generating the chip select signal for the next light emitting element array chip based on the input chip select signal.

The digital portion 800 includes a communication interface portion (hereinafter referred to as “communication IF portion”) 801, a register portion 802, a chip select signal generating portion 803, an image data storing portion 804, and pulse signal generating portions 805(1), 805(2), . . . , and 805(748). The communication IF portion 801 controls, based on the communication signal input from the CPU 703 via the communication signal line 709, the writing and reading of the set value into and from the register portion 802. The register portion 802 stores the set value required for operation. The set value includes exposure timing information to be used by the image data storing portion 804, pulse signal width and delay information to be generated by the pulse signal generating portion 805, and drive current set information to be set by the analog portion 806. The chip select signal generating portion 803 delays the chip select signal input via the chip select signal line 705 to generate the chip select signal for the next light emitting element array chip 400. The chip select signal generating portion 803 outputs the chip select signal for the next light emitting element array chip 400 to the next light emitting element array chip 400 via the chip select signal line 711.

The image data storing portion 804 stores the image data corresponding to a period in which the input chip select signal is effective, and outputs the image data to the pulse signal generating portion 805 in synchronization with the line synchronization signal. The pulse signal generating portion 805 generates the pulse signal based on the pulse signal width information and phase information which are set in the register portion 802 in accordance with the image data input from the image data storing portion 804, and outputs the pulse signal to the analog portion 806. The analog portion 806 supplies the drive current to the lower electrode 504 based on the pulse signal generated by the digital portion 800.

### Analog Portion

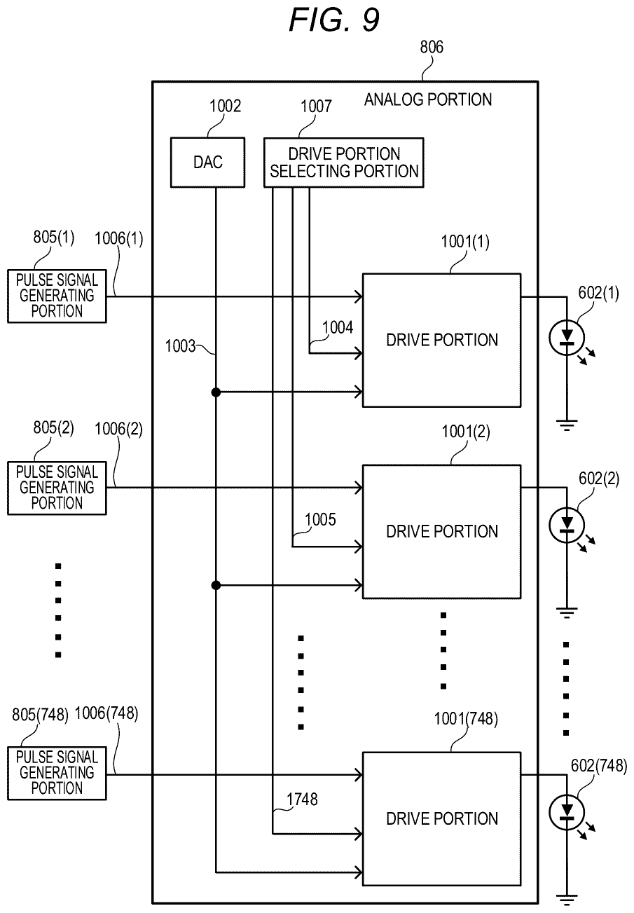

FIG. 9 is a block diagram of the analog portion 806. The analog portion 806 includes drive portions 1001(1), 1001(2), . . . , and 1001(748), a digital-to-analog converter (hereinafter referred to as “DAC”) 1002, and a drive portion selecting portion 1007. The drive portions 1001(1), 1001(2), . . . , and 1001(748) drive the 748 lower electrodes 504, respectively. The pulse signal generating portions 805(1), 805(2), . . . , and 805(748) generate the pulse signals for controlling the ON timings of the lower electrodes 504(1) to 504(748), respectively. The pulse signal generating portions 805(1), 805(2), . . . , and 805(748) input the pulse signals to the drive portions 1001(1), 1001(2), . . . , and 1001(748) via signal lines 1006(1), 1006(2), . . . , and 1006(748), respectively.

The DAC 1002 sets an analog voltage for determining the drive current in the drive portion 1001 via a signal line 1003 based on the data set in the register portion 802. The drive portion selecting portion 1007 transmits, to the drive portion 1001, a drive portion select signal for selecting the drive portion 1001 via signal lines 1004, 1005, . . . , based on the data set in the register portion 802. The drive portion select signal is generated so that only a signal connected to the selected drive portion 1001 becomes high (Hi). For example, when the drive portion 1001(1) is selected, “Hi” is supplied to only the signal line 1004. “Low” is supplied to other signal lines such as the signal line 1005 connected to the unselected drive portion 1001(2), . . . , and the signal line 1748 connected to the unselected drive portion 1001(748). The drive portion 1001 sets the analog voltage via the signal line 1003 at the timing at which each drive portion 1001 is selected by the drive portion selecting portion 1007 (timing at which the drive portion select signal becomes “Hi”). The CPU 703 sequentially selects the drive portion 1001 via the register portion 802, and sets the analog voltage corresponding to the selected drive portion 1001, to thereby set the analog voltages of all of the drive portions 1001 by one DAC 1002. With the above-mentioned operation, the pulse signal and the analog signal for determining the drive current are input to each of the drive portions 1001(1), . . . , and 1001(748), and the drive current and a light emitting time are independently controlled by a drive circuit to be described later.

### Drive Circuit

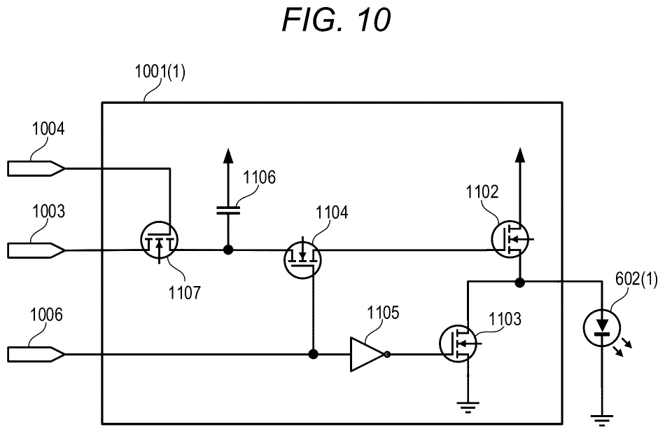

FIG. 10 is a diagram for illustrating the drive circuit of the drive portion 1001(1). The drive circuits of the drive portions 1001(2), . . . , and 1001(748) for driving the other lower electrodes 504(2), . . . , and 504(748) are similar thereto. The drive portion 1001 includes MOS-type field effect transistors (hereinafter referred to as “MOSFETs”) 1102, 1103, 1104, and 1107, an inverter 1105, and a capacitor 1106.

The MOSFET 1102 supplies a drive current to the lower electrode 504(1) in accordance with a gate voltage value. The MOSFET 1102 controls a current so that the drive current is OFF (light is turned off) when the gate voltage is at a “Low” level. A gate of the MOSFET 1104 is connected to the signal line 1006 for transmitting the pulse signal from the pulse signal generating portion 805. When the pulse signal is “Hi,” the MOSFET 1104 passes the voltage charged in the capacitor 1106 to the MOSFET 1102. A gate of the MOSFET 1107 is connected to the signal line 1004 for transmitting the drive portion select signal from the drive portion selecting portion 1007. The MOSFET 1107 is turned on when the drive portion select signal is “Hi,” and charges the capacitor 1106 with the analog voltage supplied from the DAC 1002 via the signal line 1003. In the embodiment, the DAC 1002 sets the analog voltage in the capacitor 1106 at the timing before the image formation, and the voltage level is continuously kept by keeping the MOSFET 1107 in the OFF state during the image formation period. The MOSFET 1102 supplies the drive current to the lower electrode 504(1) in accordance with the pulse signal and the analog voltage set by the above-mentioned operation.

When the input capacitor of the lower electrode 504(1) is large and an OFF-time response speed is slow, it is possible to increase the OFF speed by the MOSFET 1103. A signal obtained by logically inverting the pulse signal by the inverter 1105 is input to a gate of the MOSFET 1103. When the pulse signal is “Low,” the gate of the MOSFET 1103 is “Hi,” and the charges charged in the input capacitor between the upper electrode 508 and the lower electrode 504(1) are forcibly discharged.

As described above, the light emitting area 404 and the sealing area 409 are formed on the light emitting circuit board 402 so that the distance between the lower side 402B in the longitudinal direction LD and the light emitting area 404 is minimized. The plurality of light emitting element array chips 400 are arranged on the printed circuit board 202 in a staggered manner so that the lower sides 402B thereof are opposed to each other. In this manner, the distance between the light emitting area 404 and the rod lens array 203 can be suppressed to the minimum required distance, and the reduction of the light utilization efficiency can thus be suppressed.

According to the present embodiment, the reduction of the light utilization efficiency of the exposure head can be suppressed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1-9. (canceled)

10. An exposure head, which exposes a rotating photosensitive member, comprising:
a plurality of light emitting element array chips arranged in a staggered manner around an imaginary line along a rotation axis of the photosensitive member; and
a circuit board on which the plurality of light emitting element array chips are mounted, the plurality of light emitting element array chips including a first light emitting element array chip and a second light emitting element array chip arranged in a position different from a position of the first light emitting element array chip, each of the first light emitting element array chip and the second light emitting element array chip including:
a light emitting area including a plurality of light emitting portions; and
a sealing material for covering the light emitting area,
wherein each of the first light emitting chip and the second light emitting chip includes a first long side and a second long side, and wherein a first distance from a first side to one long side of the sealing area which is proximate to the first side is shorter than a second distance from a second side to another long side of the sealing area which is proximate to the second side, and
wherein a third distance from the first side to one long side of the light emitting area which is proximate to the first side is shorter than a fourth distance from the second side to another long side of the light emitting area which is proximate to the second side, and
wherein a distance from the one long side of the sealing area to the one long side of the light emitting area is shorter than a distance from the another long side of the sealing area to the another long side of the light emitting area, and
wherein a distance from the first side of the first light emitting chip to the imaginary line is shorter than a distance from the second side of the first light emitting chip to the imaginary line, and
wherein a distance from the first side of the second light emitting chip to the imaginary line is shorter than a distance from the second side of the second light emitting chip to the imaginary line.

11. The exposure head according to claim 10, wherein the first distance is shorter than a fifth distance from a third side which is one of two short sides of each of the plurality of light emitting element array chips to one short side of the sealing area which is parallel to and proximate to the third side, and
wherein the first distance is shorter than a sixth distance from a fourth side which is another one of the two short sides of each of the plurality of light emitting element array chips to another short side of the sealing area which is parallel to and proximate to the fourth side.

12. The exposure head according to claim 11, wherein the third distance is shorter than a seventh distance from the third side to one short side of the light emitting area which is parallel to and proximate to the third side, and
wherein the third distance is shorter than an eighth distance from the fourth side to another short side of the light emitting area which is parallel to and proximate to the fourth side.

13. The exposure head according to claim 10, wherein the third distance is shorter than a seventh distance from a third side which is one of two short sides of each of the plurality of light emitting element array chips to one short side of the light emitting area which is parallel to and proximate to the third side, and
wherein the third distance is shorter than an eighth distance from a fourth side which is another one of the two short sides of each of the plurality of light emitting element array chips to another short side of the light emitting area which is parallel to and proximate to the fourth side.

14. The exposure head according to claim 10, wherein each of the plurality of light emitting portions of the light emitting area is a top emission-type LED.

15. An image forming apparatus comprising:
a photosensitive drum;
a charger configured to uniformly charge a surface of the photosensitive drum;
an exposure head configured to expose the surface of the photosensitive drum with light in accordance with an image signal to form an electrostatic latent image, the exposure head including:
a plurality of light emitting element array chips arranged in a staggered manner around an imaginary line along a rotation axis of the photosensitive drum;
a circuit board on which the plurality of light emitting element array chips are mounted, the plurality of light emitting element array chips including a first light emitting element array chip and a second light emitting element array chip arranged in a position different from a position of the first light emitting element array chip, each of the first light emitting element array chip and the second light emitting element array chip including:
a light emitting area including a plurality of light emitting portions; and
a sealing material for covering a light emitting face of the light emitting area and a side face of the light emitting area,
wherein each of the first light emitting chip and the second light emitting chip includes a first long side and a second long side, and
wherein a first distance from a first side to one long side of the sealing area which is proximate to the first side is shorter than a second distance from a second side to another long side of the sealing area which is proximate to the second side, and
wherein a third distance from the first side to one long side of the light emitting area which is proximate to the first side is shorter than a fourth distance from the second side to another long side of the light emitting area which is proximate to the second side;
wherein a distance from the one long side of the sealing area to the one long side of the light emitting area is shorter than a distance from the another long side of the sealing area to the another long side of the light emitting area, and
wherein a distance from the first side of the first light emitting chip to the imaginary line is shorter than a distance from the second side of the first light emitting chip to the imaginary line, and
wherein a distance from the first side of the second light emitting chip to the imaginary line is shorter than a distance from the second side of the light emitting chip to the imaginary line;
a developing device configured to develop the electrostatic latent image with toner to form a toner image;
a transfer device configured to transfer the toner image onto a recording medium; and
a fixing device configured to apply heat and pressure to the toner image to fix the toner image to the recording medium.
